(19) United States
(12) Patent Application Publication
(10) Pub. No.: US 2021/0043735 A1
(43) Pub. Date: Feb. 11, 2021

(54) SHORT CHANNEL TRENCH POWER MOSFET AND METHOD

(71) Applicant: ABB SCHWEIZ AG, Baden (CH)

(72) Inventors: Renato Minamisawa, Windisch (CH); Lars Knoll, Hägglingen (CH)

(73) Assignee: ABB Power Grids Switzerland AG

(21) Appl. No.: 17/079,077

(22) Filed: Oct. 23, 2020

Related U.S. Application Data
(63) Continuation-in-part of application No. 16/149,220, filed on Oct. 2, 2018.
Application No. 16/149,220 is a continuation of application No. PCT/EP2017/058028, filed on Apr. 4, 2017.

(30) Foreign Application Priority Data
Apr. 7, 2016 (EP) 16164303.6

(51) Int. Cl. H01L 29/10; H01L 29/66; H01L 29/78

(52) U.S. Cl. CPC H01L 29/1095; H01L 29/66068; H01L 29/1608; H01L 29/1045; H01L 29/7813

(57) ABSTRACT

An embodiment provides a power semiconductor device having a low on-state resistance while avoiding any short channel effects and having a low subthreshold slope. The embodiment provides a trench power semiconductor device, which comprises a compensation layer of a first conductivity type, wherein the compensation layer is extending on a gate insulation layer between a source layer of the first conductivity type and a substrate layer of the first conductivity type directly adjacent to a channel region of a second conductivity type.

### CROSS-REFERENCE TO RELATED APPLICATIONS

This application is a continuation-in-part of U.S. Non-Provisional application Ser. No. 16/149,220, filed on Oct. 2, 2018, which claims priority to PCT/EP2017058028 filed Apr. 4, 2017, which claims priority to European Patent Application No. 16164303.6 filed Apr. 7, 2016, all of which applications are hereby incorporated herein by reference.

### TECHNICAL FIELD

The present invention relates to a short channel trench power MOSFET, and to a method for manufacturing the same.

### BACKGROUND

From US 2014/0159053 A1 there is known a silicon carbide trench gate transistor comprising an n-type drain region, an n-type drift region formed on the n-type drain region, a p-type base region formed on the n-type drift region, an n-type source region formed on the p-type base region, a gate trench and an n-type embedded channel region located under the source region and in the base region on the sidewall of the gate trench. The embedded channel region is described to have a thickness of 30 to 80 nm.

From US 2014/0110723 A1 there is known a semiconductor device that includes: a semiconductor substrate; a first silicon carbide semiconductor layer located on a principal surface of the semiconductor substrate, the first silicon carbide semiconductor layer including a drift region of a first conductivity type, a body region of a second conductivity type, and an impurity region of a first conductivity type; a trench provided in the first silicon carbide semiconductor layer so as to reach inside of the drift region; a second silicon carbide semiconductor layer of the first conductivity type located at least on a side surface of the trench so as to be in contact with the impurity region and the drift region; a gate insulating film; a gate electrode; a first ohmic electrode; and a second ohmic electrode. The body region includes a first body region which is in contact with the second silicon carbide semiconductor layer on the side surface of the trench, and a second body region which is in contact with the drift region and has a smaller average impurity concentration than the first body region. A thickness of the second silicon carbide semiconductor layer in a range from 20 nm to 70 nm is disclosed.

Among different structures of power metal oxide semiconductor field effect transistor (MOSFET) devices, trench power MOSFETs have the advantage that the on-state resistance is relatively low. In a trench power MOSFET a current is conducted vertically from a source electrode on a first main side (i.e. a first main side surface) of the wafer to a drain electrode on a second main side (i.e. a second main side surface) of the wafer opposite to the first main side. To achieve a high drive capability a plurality of trenches penetrate through a p-doped body region below the first main side of the wafer. Inside of each trench there is formed a gate dielectric and a gate electrode to control the current conduction from an n-doped source region through a channel region in the p-doped body region adjacent to the trenches to an n⁻-doped drift region by the field effect.

Each trench corresponds to a MOSFET cell. All the MOSFET cells are connected between the source electrode and the drain electrode in parallel in order to reduce the on-state resistance. The n⁻-doped drift region between the channel regions of the plurality of MOSFET cells and an n⁺-doped drain layer in contact with the drain electrode allows a large voltage in off-state condition. In the on-state condition, the charge carriers drift through the n⁻-drift region towards the n⁺-doped drain layer due to the potential difference across it.

The power semiconductor industry is strongly moving toward scaling, which requires the improvement of the device electrostatics. Reducing the channel length in the known trench power MOSFET can strongly reduce on-state losses, however, at the cost of a shift of the threshold voltage Vₜₕ and at the cost of early breakdown in reverse blocking.

For a high reverse blocking capability it is crucial to design the p-doped body region in a way to avoid leakage current under depletion to the n⁺-doped source region. In a common trench power MOSFET the p-doped body region is implemented as a semiconductor layer having a typical thickness of about 1 μm and a moderate doping concentration of about 10¹⁷ cm⁻³. Reducing the layer thickness of the p-doped body region and thus reducing the channel length would inevitably require higher doping, which in turn, would degrade the channel mobility due to coulombic scattering and significant shift of Vₜₕ towards positive polarity.

From prior art document U.S. Pat. No. 8,476,697 B1 there is known a silicon carbide (SiC) power double-diffused metal oxide semiconductor field effect transistor (DMOSFET) having a channel length of about 0.5 μm. A p-doped body region has a peak concentration of about 1·10¹⁸ cm⁻³ to 3·10¹⁸ cm⁻³ in order to avoid punch-through. The doping profile of the p-doped body region is a retrograde doping profile with p-type doping concentration of about 2.5·10¹⁷ cm⁻³ or greater in a channel region and about 1˜10¹⁸ cm⁻³ to 3·10¹⁸ cm⁻³ near the p-n junction between the p-doped body region and the n⁻-doped drift region. In order to avoid high oxide fields at threshold the channel region is counter-doped with an n-type dopant with a doping concentration of about 3·10¹⁷ cm⁻³ to 8·10¹⁷ cm⁻³, whereby, after compensation, the surface is n-type with a net doping concentration of about 1·10¹⁷ cm⁻³ to 3·10¹⁷ cm⁻³ up to a counter doping depth of 60 nm. There is also described a silicon carbide UMOSFET device, wherein a surface n-type layer is obtained by angled ion implantation into the trench sidewalls following trench etch. However, the power MOSFETs disclosed in U.S. Pat. No. 8,476,697 B1 suffer from short-channel effects and a high subthreshold slope.

### SUMMARY

Embodiments of the invention provide a power semiconductor device having a low on-state resistance while avoiding any short channel effects and having a low subthreshold slope.

The power semiconductor device according to the invention is a trench power field effect transistor, which comprises a compensation layer of a first conductivity type, wherein the compensation layer is extending on a gate insulation layer between a source layer and a substrate layer directly adjacent to a channel region, and wherein:

$${L}_{c h} > 4 √ ( \frac{( {ɛ}_{C R} {c}_{COMP} {t}_{GI} )}{{ɛ}_{GI}} ) , \qquad ( 1 )$$

In the above equation (1), L_{ch} is a channel length, ε_{CR} is a permittivity of the channel region, ε_{GI} is a permittivity of the gate insulation layer, t_{COMP} is a thickness of the compensation layer in a direction perpendicular to the interface between the gate insulation layer and the compensation layer, and t_{GI} is a thickness of the gate insulation layer. Therein, the channel length is defined as the length of a shortest path along the gate insulation layer from the source layer to the substrate layer. Due to the compensation layer having the same conductivity type as the source layer, it might be difficult to decide at what depth (i.e. at what distance from the first main side surface of the wafer) the source layer ends and the compensation layer begins. For the purpose of determining the channel length, the depth, at which the source layer ends and the compensation layer begins, is therefore assumed to be the depth of the p-n junction between the source layer and the body layer at a lateral distance of 0.1 μm from the gate insulation layer. Likewise, for the purpose of determining the channel length, the depth, at which the compensation layer ends and the substrate layer begins is assumed to be the depth of the p-n junction between the body layer and the substrate layer at a lateral distance of 0.1 μm from the gate insulation layer. Throughout the specifications the term lateral refers to a direction parallel to the first main side of the wafer.

By satisfying equation (1) the compensation layer can avoid short channel effects in a trench power field effect transistor device with a low subthreshold slope and an optimum threshold voltage even for a short channel length where prior art trench power field effect transistors show significant short channel effects.

In the power semiconductor device of the invention a thickness of the compensation layer is in a range from 1 nm to 10 nm. The thickness is measured in a direction perpendicular to the gate insulation layer. The lower limit of 1 nm ensures efficient reduction of the threshold voltage Vₜₕ and increase of the channel carrier mobility, while the upper limit ensures that short channel effects can be reduced especially efficient.

Further developments of the invention are specified in the dependent claims.

In exemplary embodiments the thickness of the compensation layer is in a range from 2 nm to 5 nm.

In exemplary embodiments the channel length is less than 0.5 μm or less than 0.3 μm. Such short channel length results in a low on-state voltage, i.e. in low on-state losses.

In an exemplary embodiment a doping concentration in the compensation layer is at least 1·10¹⁸ cm⁻³ or at least 5·10¹⁸ cm⁻³. Such high doping concentration of the compensation layer results in most efficient reduction of short channel effects and reduction of the threshold voltage by the compensation layer. Throughout this specification a doping concentration of a layer or region shall refer to a peak net doping concentration of the layer, i.e. to a maximum net doping concentration of this layer, unless it is referred to a doping profile. If it is referred to a doping profile then the term doping concentration shall refer to a local net doping concentration.

In an exemplary embodiment a doping concentration in the channel region is at least 1·10¹⁷ cm⁻³ or at least 5·10¹⁷ cm⁻³ or at least 1·10¹⁸ cm⁻³, with a maximum of 5·10¹⁸ cm⁻³. In another example, the doping concentration in the channel region is at least 1·10¹⁷ cm⁻³ with a maximum of 5·10¹⁷ cm⁻³. Such high doping concentration in the channel region can efficiently avoid punch-through in the blocking state at high reverse voltages. In an exemplary embodiment, a doping concentration in the body main region is higher than that of the channel region, for example the body main region having a doping concentration of at least 1·10¹⁸ cm⁻³, or for example between 1·10¹⁸ cm⁻³ and 5·10¹⁹ cm⁻³. The compensation layer can have a higher doping concentration than the channel region, but in some embodiments it still may help even having a bit lower doping concentration than the channel region.

In an exemplary embodiment the substrate layer, the body layer, the compensation layer and the source layer are silicon carbide layers. Silicon carbide (SiC) has a breakdown strength which is about ten times higher than that of silicon (Si), resulting in much lower losses for SiC-based devices.

In an exemplary embodiment the power semiconductor device comprises a well region of the second conductivity type, wherein the well region is directly adjacent to the gate insulation layer below a bottom of the gate electrode. Such well region can efficiently protect the gate insulation layer against high electric fields.

The power semiconductor device of the invention may be manufactured by a method according to claim 11. Performing the step of deepening the trench by removing material of the second semiconductor layer and of the first semiconductor layer such that the deepened trench penetrates into the first semiconductor layer only after the step of applying an impurity of the first conductivity type into a sidewall of the at least one trench allows to apply the impurity of the first conductivity type only into the second semiconductor layer and the third semiconductor layer, while avoiding to apply the impurity of the first conductivity type into the first semiconductor layer.

In exemplary embodiments applying the impurity of the first conductivity type into the sidewall of the at least one trench is performed by angled ion implantation or by plasma immersion ion implantation (PIII). Plasma immersion ion implantation allows for the formation of the compensation layer with a homogeneous doping concentration profile along a direction parallel to the sidewall of the trench, i.e. a doping concentration profile, which is nearly independent from the depth in the trench. Furthermore, plasma immersion ion implantation only few defects are created, which further reduces the short channel effects.

### BRIEF DESCRIPTION OF THE DRAWINGS

Detailed embodiments of the invention will be explained below with reference to the accompanying figures, in which:

FIG. 1 shows a partial cross sectional view of a power semiconductor device according to an embodiment of the invention;

FIG. 2 shows an enlarged portion of the cross sectional view in FIG. 1; and

FIGS. 3A to 31, collectively FIG. 3, show partial cross sectional views illustrating different steps of a method for manufacturing the power semiconductor device of FIG. 1.

The reference signs used in the figures and their meanings are summarized in the list of reference signs. Generally, similar elements have the same reference signs throughout the specification. The described embodiments are meant as examples and shall not limit the scope of the invention.

### DETAILED DESCRIPTION OF ILLUSTRATIVE EMBODIMENTS

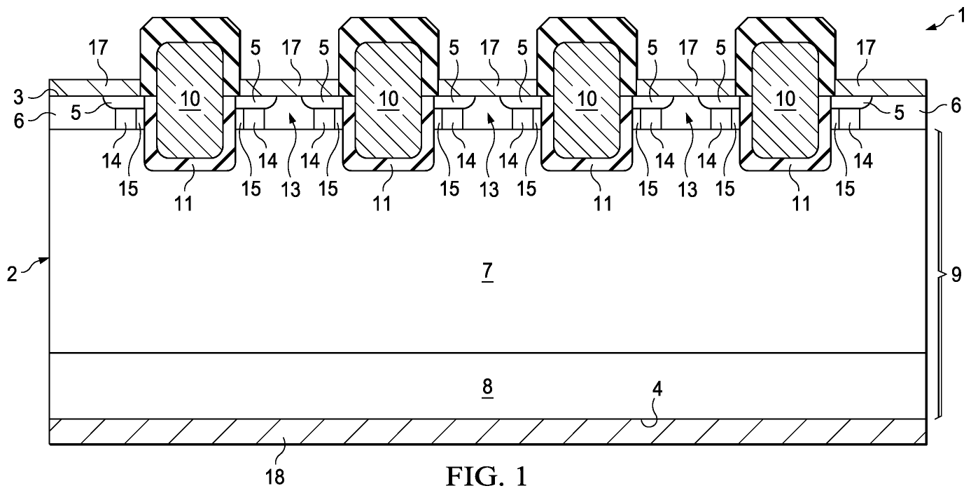

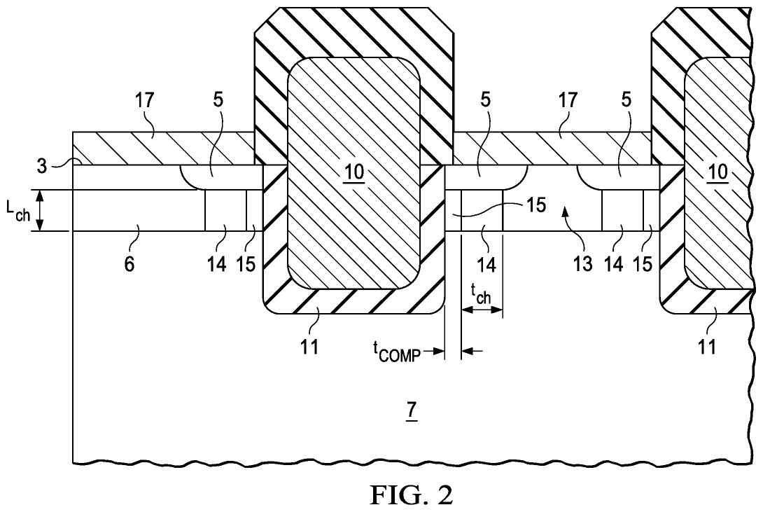

In FIG. 1 there is shown a cross sectional view of a power semiconductor device according to an embodiment of the invention. FIG. 2 shows an enlarged portion of FIG. 1. The power semiconductor device according to the embodiment of the invention is a trench power metal oxide semiconductor field effect transistor (MOSFET) 1. It comprises a silicon carbide (SiC) wafer 2 having a first main side 3 and a second main side 4. Throughout the specification the term silicon carbide may refer to any polytype of silicon carbide, in particular it may refer to 4H-SiC or 6H-SiC.

In an order from the first main side 3 to the second main side 4, the SiC wafer 2 comprises an n⁺-doped source layer 5, a p-doped body layer 6, an n⁻-doped drift layer 7 and an n⁺-doped drain layer 8. The drift layer 7 and the drain layer 8 form an n-doped substrate layer 9. The source layer 5 is separated from the drift layer 7 by the body layer 6, and the body layer 6 is separated from the drain layer 8 by the drift layer 7. A plurality of electrically conductive gate electrodes 10 penetrate through the body layer 6.

Each gate electrode 10 is configured to control an electrical conductivity of a channel region 14 in the body layer 6 by an electrical field when applying an electrical potential to the gate electrode 10. Therein, each channel region 14 is a portion of the body layer 6, which extends from the source layer 5 to the drift layer 7. The remainder of body layer 6 forms body main region 13, which has a higher doping compensation than the channel region 14. A MOS channel may be formed from the source layers 5 via the channel regions 14 to the drift layer 7. A gate insulation layer 11 electrically insulates the gate electrode 10 from the drift layer 7, from the body layer 6 and from the source layer 5.

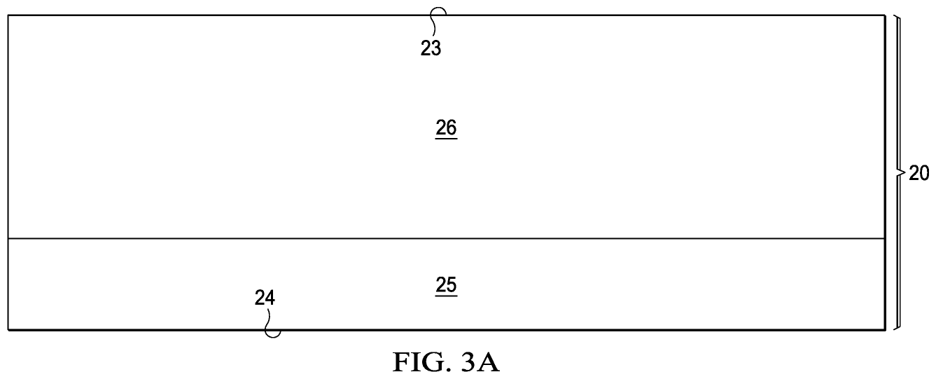

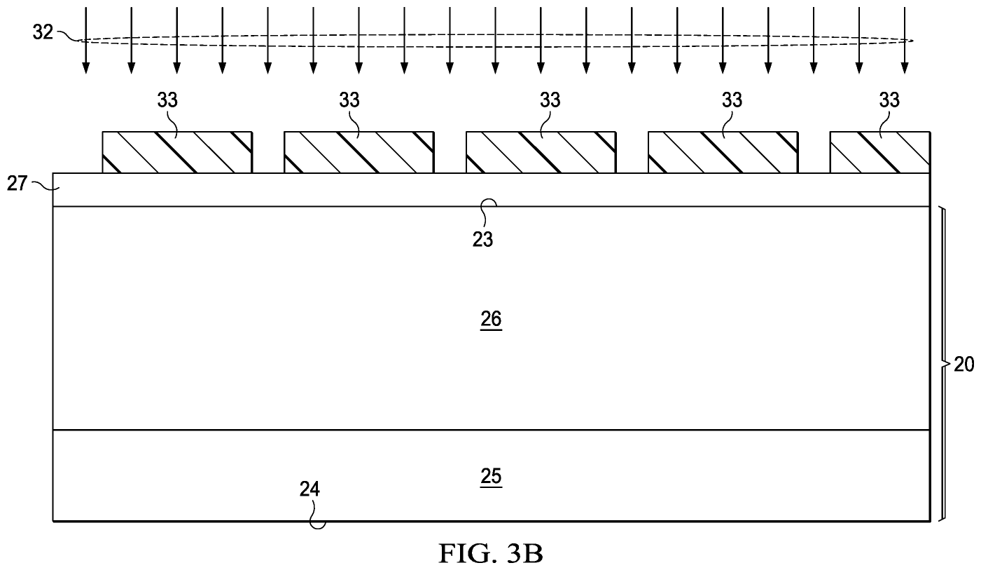

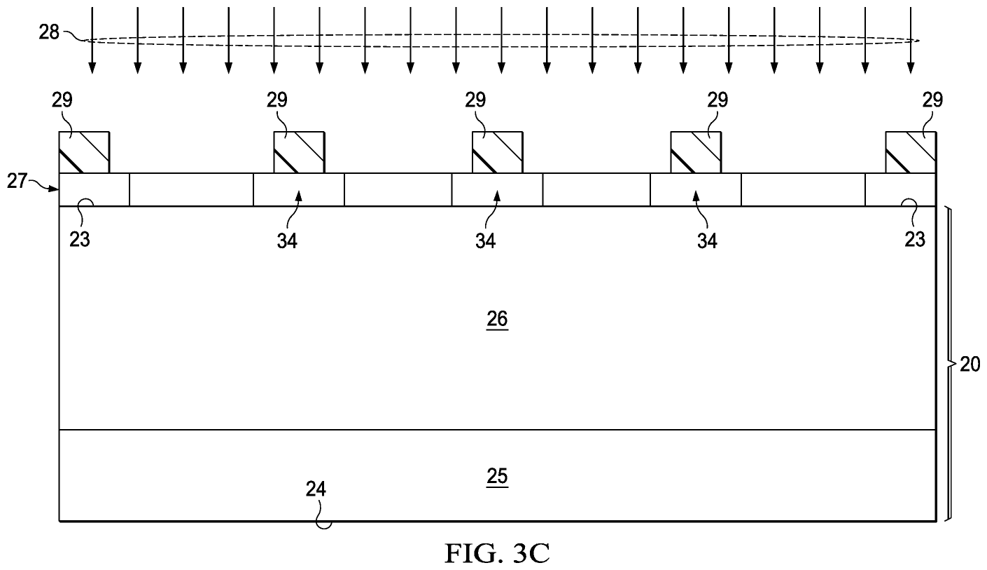

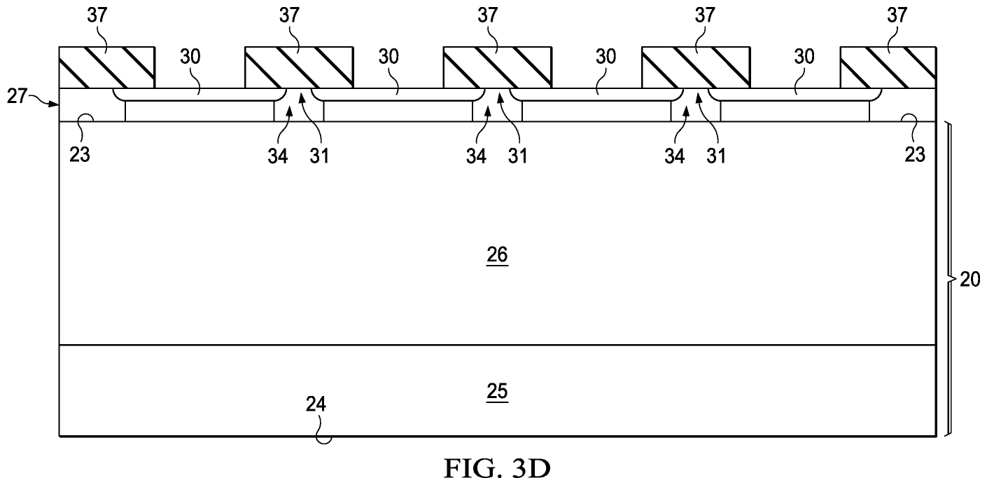

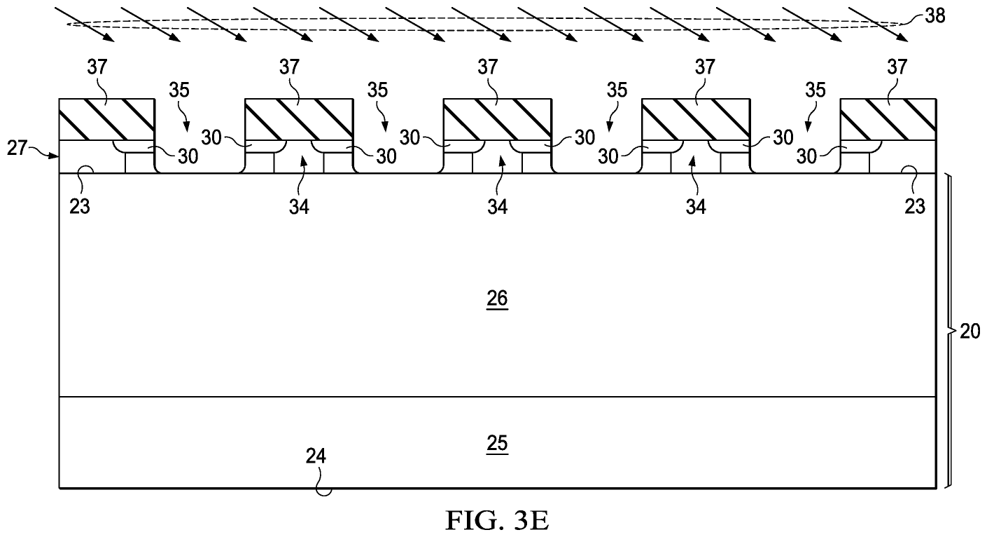

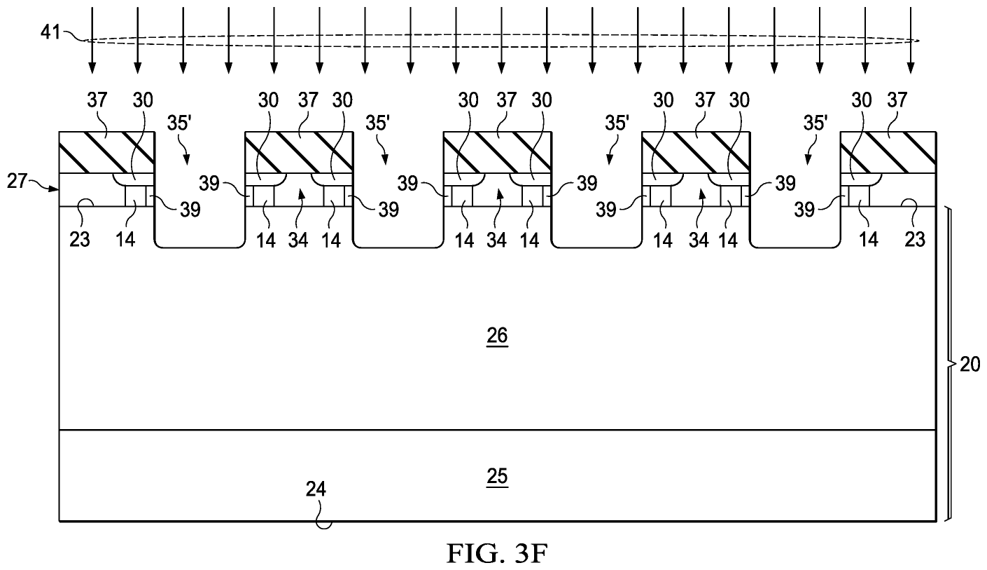

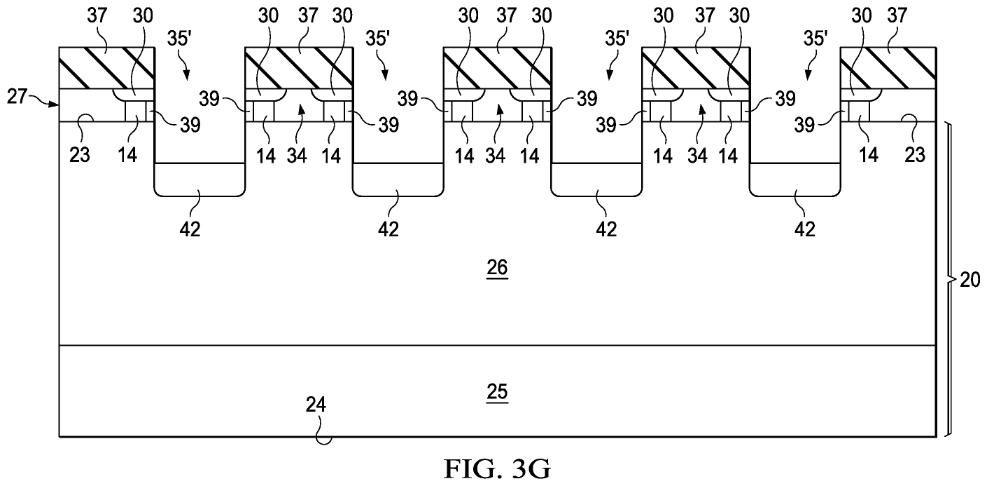

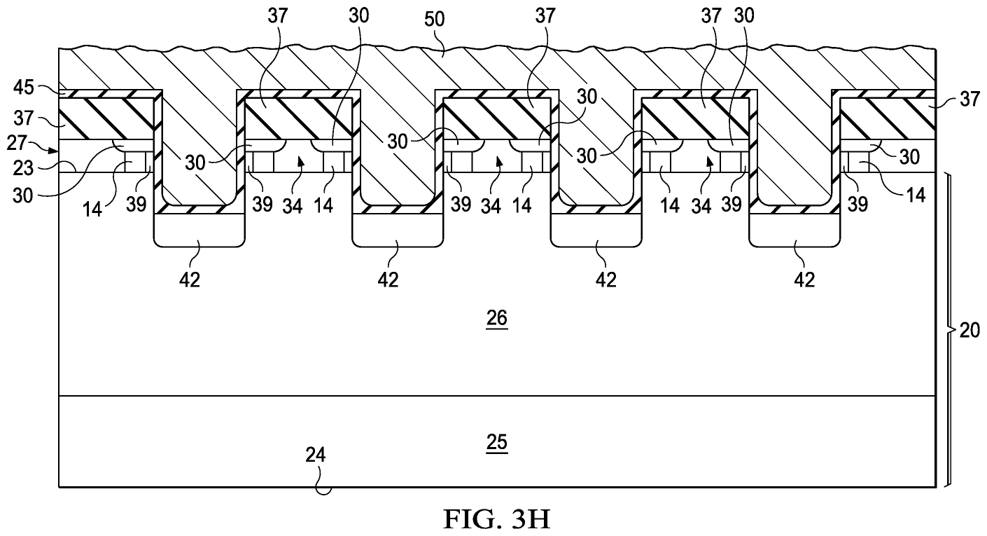

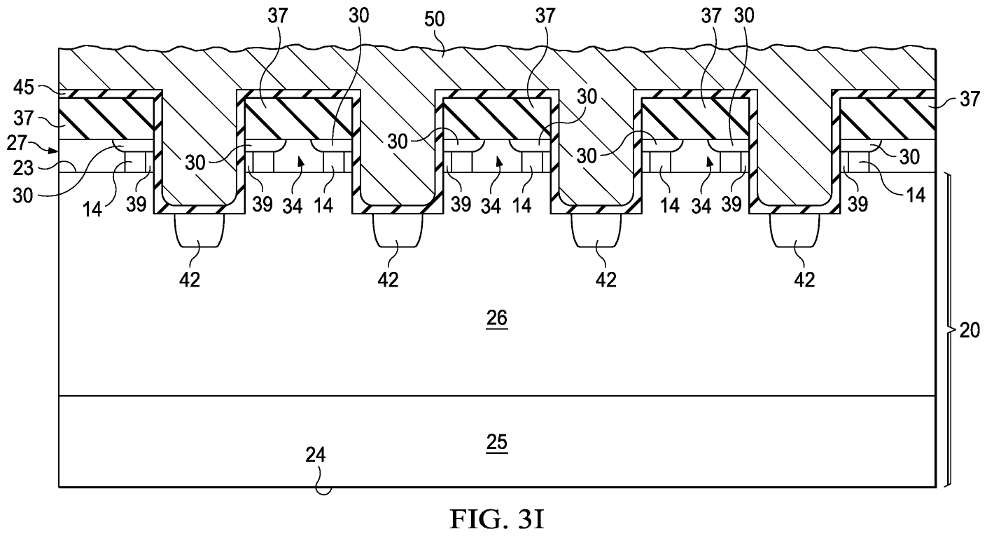

Channel doping concentration of layer 14 can be lower (e.g., by a factor of 5×) than the body region 13 because of the additional electrostatic doping effect of the gate electrode 10. In the center of the body region 34 the gate effect is smaller and thus should be compensated with higher p doping. If the channel region 14 is too wide, the electrostatic doping of the gate electrode will not be strong enough to ensure device blocking. Thus the channel region should be thin, e.g., as described herein. As will be clear from process steps of FIG. 3, embodiments of the invention demonstrate a way to form a thin channel region in a trench device using a self-aligned method.

Directly adjacent to the channel region 14 an n-doped compensation layer 15 extends on the gate insulation layer 11 between the source layer 5 and the drift layer 7. A thickness t_{COMP} of the compensation layer 15 in a direction perpendicular to the interface between the gate insulation layer 11 and the compensation layer 15, a channel length L_{ch}, which is defined as the length of the shortest path from the source layer 5 to the drift layer 7 on the interface between the gate insulation layer 11 and the compensation layer 15, and a thickness t_{GI} of the gate insulation layer 11 in a direction perpendicular to the interface between the gate insulation layer 11 and the compensation layer 15 fulfil the following in equation:

$${L}_{c h} > 4 √ ( \frac{( {ɛ}_{C R} {c}_{COMP} {t}_{GI} )}{{ɛ}_{GI}} ) , \qquad ( 1 )$$

wherein ε_{CR} is a permittivity of the channel region and ε_{GI} is a permittivity of the gate insulation layer 11. As indicated above, due to the compensation layer 15 having the same conductivity type as the source layer 5, it might be difficult to decide at what depth (i.e. at what distance from the first main side 3 of the SiC wafer 2) the source layer 5 ends and the compensation layer 15 begins.

For the purpose of determining the channel length L_{ch}, the depth, at which the source layer 5 ends and the compensation layer 15 begins, is assumed to be the depth of the p-n junction between the source layer 5 and the body layer 6 at a lateral distance of 0.1 μm from the gate insulation layer 11. Likewise, for the purpose of determining the channel length L_{ch}, the depth, at which the compensation layer 15 ends and the drift layer 7 begins, is assumed to be the depth of the p-n junction between the body layer 6 and the drift layer 7 at a lateral distance of 0.1 μm from the gate insulation layer 11. The channel region 14 is defined as a portion of the body layer 6, the electrical conductivity of which can be controlled by applying an electrical potential to the gate electrode 10. Exemplarily, the channel region 14 is defined as a portion of the body layer which has a distance of less than 0.1 μm from the compensation layer 15, shown as ten in FIG. 2.

The thickness t_{COMP} of the compensation layer 15 is in a range from 1 nm to 10 nm, exemplarily in a range from 2 nm to 5 nm. The channel length L_{ch} may be less than 0.5 μm, exemplarily less than 0.3 μm. In the power semiconductor device according to the present embodiment the interface between the gate insulation layer 11 and the compensation layer 15 is vertical to the first main side 3. In this case the channel length L_{ch} corresponds to a distance between the source layer 5 and the drift layer 7 at a lateral distance tₑ of 0.1 μm from the gate insulation layer 11, which is the thickness of the body layer 6 in a direction perpendicular to the first main side 3 at a lateral distance of 0.1 μm from the gate insulation layer 11.

A doping concentration in the compensation layer 15 may be at least 1·10¹⁸ cm⁻³, for example at least 5·10¹⁸ cm⁻³. A doping concentration in the channel region 14 may be at least 1·10¹⁷ cm⁻³, exemplarily at least 5·10¹⁷ cm⁻³, for example at least 1·10¹⁸ cm⁻³, with a maximum of 5·10¹⁸ cm⁻³. For example, the doping concentration in channel region 14 can be at least 1·10¹⁷ cm⁻³ with a maximum of 5·10¹⁷ cm⁻³. A doping concentration in the body main region 13 is higher than that of the channel region 14, for example, between 1·10¹⁸ cm⁻³ and 5·10¹⁹ cm⁻³. The compensation layer can have a higher doping concentration than the channel region, but in some embodiments it still may help even having a bit lower doping concentration than the channel region.

A thickness of the drift layer 7 depends on the nominal voltage, i.e. on the maximum blocking voltage in reverse direction, for which the device is designed. For example, a nominal blocking voltage of 1 kV requires a thickness of the drift layer 7 of about 6 μm and a nominal blocking voltage of 5 kV requires a thickness of the drift layer 7 of about 36 μm. The ideal doping concentration of the drift layer 7 depends also on the nominal voltage and is exemplarily in a range between 1·10¹⁵ cm⁻³ and 5·10¹⁶ cm⁻³. A thickness of the source layer 5 is exemplarily in a range between 0.5 μm and 5 μm, while a doping concentration of the source layer 5 is exemplarily 1·10¹⁸ cm⁻³ or more.

A source electrode 17 is arranged on the first main side 3 of the SiC wafer 2. It forms an ohmic contact to the source layer 5. To avoid triggering of a parasitic bipolar transistor formed by the body layer 6, the source layer 5 and the drift layer 7, the body layer 6 is also electrically connected to the source electrode 17. On the second main side 4 of the SiC wafer 2 a drain electrode 18 is arranged, which forms an ohmic contact to the drain layer 8.

Below each gate electrode 10 there is formed a p-doped well region 42 directly adjacent to the gate insulation layer 11 below a bottom of the gate electrode 10. The well region 42 is separated from the body layer 6 by the drift layer 7. The well region 42 can efficiently protect the gate insulation layer 11 against high electric fields.

In a plane parallel to and below the first main side 3, gate electrodes 10, may have a cross-section of any shape, exemplarily a longitudinal line shape, a honeycomb shape, a polygonal shape, a round shape or an oval shape.

Referring to FIG. 3, a method for manufacturing the power semiconductor device according to the embodiment of the invention shown in FIGS. 1 and 2 is described. In a first method step an n-doped first semiconductor layer 20 is provided as shown in FIG. 3A. The first semiconductor layer 20 has a first main side 23 and a second main side 24 opposite to the first main side 23. It includes an n⁺-doped SiC layer 25, which forms the drain layer 8 in the final trench power MOSFET 1, and an n⁻-doped SiC layer 26, which forms the drift layer 7 in the final trench power MOSFET 1. The n⁺-doped SiC layer 25 may be a SiC substrate wafer on which the n⁻-doped SiC layer 26 is deposited epitaxially by chemical vapor deposition (CVD), for example. Alternatively, the n⁻-doped SiC layer 26 may be a substrate wafer, on which the n⁺-doped SiC layer 25 is deposited epitaxially by CVD, for example, or in which the n⁺-doped SiC layer 25 may be formed by applying a p-type dopant by ion implantation, for example.

Thereafter further doping is performed on second semiconductor layer 27 as shown in FIG. 3B, to form p-doped body main regions 34 in second semiconductor layer 27 as shown in FIG. 3C. The p-doped body main regions 34 may be formed by applying a p-type dopant 32 into the second semiconductor layer 27 by ion implantation, for example using an implantation mask 33 as illustrated in FIG. 3B. The p-doped body main regions 34 thus are doped to a higher concentration than the remainder of p-doped semiconductor layer 27, which remainder will be used to form lower-doping concentration channel regions 39. Forming the body main regions 34 by ion implantation requires a subsequent activation of the implanted impurity by heat treatment. In the final trench power MOSFET 1 the p-doped body main region 34 forms the p-doped body main region 13.

Thereafter a p-doped second semiconductor layer 27 is formed on the first main side 23 of the first semiconductor layer 20 to be in direct contact with the first semiconductor layer 20 as shown in FIG. 3C. The second semiconductor layer 27 may be deposited epitaxially onto the n⁻-doped SiC layer 26 by CVD, for example, or it may be formed by applying a p-type dopant by ion implantation, for example, into the first semiconductor layer 20 from its first main side 23. Forming the second semiconductor layer 27 by ion implantation requires a subsequent activation of the implanted impurity by heat treatment. In the final trench power MOSFET 1 the second semiconductor layer 27 forms the p-doped body layer 6.

Thereafter an n⁺-doped third semiconductor layer 30, which is in direct contact with the second semiconductor layer 27 and which is separated from the first semiconductor layer 20 by the second semiconductor layer 27, is formed as shown in FIG. 3C. Specifically, the third semiconductor layer 30 may be formed by applying a first n-type impurity 28 into the second semiconductor layer 27 by ion implantation, for example, using an implantation mask 29 as illustrated in FIG. 3C. Forming the third semiconductor layer 30 by ion implantation requires a subsequent activation of the implanted impurity by heat treatment. The third semiconductor layer 30 has openings 31 as shown in FIG. 3D through which the second semiconductor layer 27 is exposed for forming an electrical contact to the source electrode 17 at a later stage (see FIG. 1). In the final trench power MOSFET 1 the third semiconductor layer 30 forms the source layer 5.

In a next method step a plurality of trenches 35 is formed in the stack of the first to third semiconductor layer 20, 27 and 30 such that the trench 35 penetrates through the third semiconductor layer 30 into the second semiconductor layer 27 by removing material of the second semiconductor layer 27 and of the third semiconductor layer 30. Removing material of the second semiconductor layer 27 and of the third semiconductor layer 30 can exemplarily be done by selective etching of the second semiconductor layer 27 and of the third semiconductor layer 30 using an etching mask 37 as shown in FIGS. 3D and 3E. The trench 35 has a depth at or close to the interface between the first semiconductor layer 20 and the second semiconductor layer 27.

This etching step is shown as self-aligned, e.g., using the mask from FIG. 3C and inverting it, that is, planarization and removal of first mask. Forming layers 34, 14 and 39 via self-aligned implantation and trench etching can ensure the feasibility of the required dimensions.

After forming the trenches 35, a second n-type impurity 38 is applied into a sidewall of each trench 35 to form an n-doped semiconductor region 39, which extends from the third semiconductor layer 30 to the first semiconductor layer 20 as shown in FIGS. 3E and 3F. The depth of the trench 35 has to be close enough to the interface between the first semiconductor layer 20 and the second semiconductor layer 27 to form the n-doped semiconductor region 39 to extend from the third semiconductor layer 30 to the first semiconductor layer 20. On the other side applying the second n-type impurities 38 into the first semiconductor layer 20 should be avoided or reduced to a minimum. To achieve the latter goal, the trench 30 should not extend into the first semiconductor layer 20.

The second n-type impurity 38 may be applied into the sidewall of each trench 35 by angled ion implantation by plasma immersion ion implantation. The inclined arrows in FIG. 3E refer to angled ion implantation having an implantation angle between 20 degrees and 60 degrees, for example, between 40 degrees and 50 degrees or even between 43 degrees and 47 degrees. The arrows in FIG. 3E are directed only in one direction. However, when angled ion implantation is used, a plurality of different angels is used to achieve a homogeneous doping concentration profile along the sidewalls of trenches 35, respectively.

After the step of applying the second n-type impurity 38 into the sidewall of each trench 35 the trenches 35 are deepened by removing material of the second semiconductor layer 27 and of the first semiconductor layer 20 such that the deepened trenches 35′ penetrate into the first semiconductor layer 20, respectively, as shown in FIG. 3G. Removing material of the second semiconductor layer 27 and of the first semiconductor layer 20 may be performed by an etching step using etching mask 37. A p-doped semiconductor well region 42 may be formed below a bottom of each deepened trench 35′ by applying a p-type impurity 41 into the first semiconductor layer 20 through the bottom of each deepened trench 35′ as shown in FIGS. 3F and 3G.

The implantation process self-aligns the well region 42 with the to-be formed gate electrode 10, 50; that is, the well region 42 has the same lateral dimension or extension as the gate insulation layer 11, 45 or trench 35, 35′. A spacer at the trench sidewall can be used to narrow the implantation region 42 by 50 nm to 200 nm. In certain embodiments, the width of the trench and well region is can be 2 micrometers or less, for example, 1.5 micrometer or even 1 micrometer or below. In the self-aligned process described above, the same mask 37 thus may be used to etch the trench 35, form the compensation layer 15, 39, extend the trench 35′, and form the well region 42, thus allowing such relatively small trench widths.

In a next method step an insulation layer 45 is formed to cover the sidewall and the bottom of each deepened trench 35′ and thereafter an electrode layer 50 is formed in the deepened trench 35′ on the insulation layer 45 as shown in FIG. 3H. Therein, the electrode layer 50 is electrically insulated from the first semiconductor layer 20, the second semiconductor layer 27, the third semiconductor layer 30 and the n-doped semiconductor region 39 by the insulation layer 45. Before forming the insulation layer 45 the etching mask 37 is removed by selective etching, for example. The electrode layer 50 may be a polysilicon layer, for example, and the insulation layer may be a silicon oxide layer, for example. In the final trench power MOSFET 1 shown in FIGS. 1 and 2 the electrode layer 50 forms the gate electrodes 10 and the insulation layer 45 forms the gate insulation layer 11.

Next, the electrode layer 50 is structured (i.e. any material of the electrode layer 50 which is no material of the gate electrodes 10 in the final device 1 is removed) and covered by an additional insulation layer, the source electrode 17 is formed on the third semiconductor layer 30 and the drain electrode 18 is formed on the second main side 24 of the first semiconductor layer 20 to obtain the final trench power MOSFET 1 as shown in FIGS. 1 and 2.

Referring now to FIG. 3, the width of p+ region 42 has been reduced to reduce JFET effect. In highly scaled devices, e.g., 2 um and below, the p+ regions 42 can have a negative effect on the conduction as they deplete the region 26 between the trenches. A reduction of the p+ reduces the effect but should be small, e.g., 50 nm to 500 nm, to avoid device variation.

In the description above, a specific embodiment was described. However, alternatives and modifications of the above described embodiment are possible.

In the above described method for manufacturing the power semiconductor device shown in FIG. 1 the third semiconductor layer 30 is formed by applying the first n-type impurity 28 into the second semiconductor layer 27 by ion implantation, for example, using the implantation mask 29 as illustrated in FIG. 3C. However, it is also possible to form the third semiconductor layer 30 by other methods, such as epitaxially on the second semiconductor layer 27 by CDV, for example.

In the above described embodiment of the invention the trench power MOSFET 1 comprises the p-doped well region 42 for protecting the gate insulation layer 11 against high electric fields. However, in a modified embodiment the trench power MOSFET 1 does not include the p-doped well region 42.

In the above description a trench power MOSFET 1 was described as an embodiment of the power semiconductor device of the invention. However, the invention is not limited to a trench power MOSFET. For example, another embodiment of the power semiconductor device of the invention is a trench insulated gate bipolar transistor (IGBT). Such trench IGBT differs from the trench power MOSFET 1 described above in an additional p-doped layer on the second main side 4 of the SiC wafer 2.

The above embodiments were explained with specific conductivity types. The conductivity types of the semiconductor layers in the above described embodiments might be switched, so that in a specific embodiment all layers which were described as p-type layers would be n-type layers and all layers which were described as n-type layers would be p-type layers. For example, in a modified embodiment, the source layer 5 may be a p-doped layer, the body layer 6 may be an n-doped layer, and the substrate layer 9 may be a p-doped layer.

It should be noted that the term “comprising” does not exclude other elements or steps and that the indefinite article “a” or “an” does not exclude the plural. Also elements described in association with different embodiments may be combined.

The following reference numerals can be used in conjunction with the drawings:
1 trench power metal oxide semiconductor field effect transistor (MOSFET)
2 silicon carbide (SiC) wafer
3, 23 first main side
4,24 second main side
5 (n⁺-doped) source layer
6 (p-doped) body layer
7 (n⁻-doped) drift layer
8 (n⁺-doped) drain layer
9 (n-doped) substrate layer
10 gate electrode
11 gate insulation layer
13 body main region
14 channel region
15 (n-doped) compensation layer
17 source electrode
18 drain electrode
20 (n-doped) first semiconductor layer
23 first main side
24 second main side
n⁺-doped SiC layer
26 n⁻-doped SiC layer
27 (p-doped) second semiconductor layer
28 first n-type impurity
29 implantation mask
30 (n⁺-doped) third semiconductor layer
31 opening
32 p-type impurity
33 body main region implantation mask
34 body main region
35 trench
35′ deepened trench
37 etching mask
38 second n-type impurity
39 n-doped semiconductor region
41 p-type impurity
42 p-doped well region
45 insulation layer
50 electrode layer
L_{ch} channel length
t_{COMP} thickness of the compensation layer 15
t_{ch} thickness of the channel region 14

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A power semiconductor device comprising:
a substrate layer having a first conductivity type;
a body layer provided on the substrate layer and having a second conductivity type, which is different from the first conductivity type;
a source layer provided on the body layer and having the first conductivity type, wherein the body layer comprises:
a channel region extending from the source layer to the substrate layer; and
a body main region adjacent the channel region, wherein a body main region doping concentration is higher than a channel region doping concentration;
an electrically conductive gate electrode penetrating through the body layer for controlling electrical conductivity of the channel region;
a gate insulation layer electrically insulating the gate electrode from the substrate layer, from the body layer and from the source layer; and
a compensation layer of the first conductivity type, which is extending directly on the gate insulation layer between the source layer and the substrate layer directly adjacent to the channel region opposite the body main region, the channel region being defined as a portion of the body layer which has a distance of less than 0.1 μm from the compensation layer, wherein:
$${L}_{c h} > 4 √ ( \frac{( {ɛ}_{C R} {c}_{COMP} {t}_{GI} )}{{ɛ}_{GI}} ) ;$$
wherein L_{ch} is a channel length, ε_{CR} is a permittivity of the channel region, ε_{GI} is a permittivity of the gate insulation layer, t_{COMP} is a thickness of the compensation layer in a direction perpendicular to an interface between the gate insulation layer and the compensation layer, and t_{GI} is a thickness of the gate insulation layer; and
wherein the thickness t_{COMP} of the compensation layer is in a range from 1 nm to 10 nm.

2. The power semiconductor device according to claim 1, wherein the thickness t_{COMP} of the compensation layer is in a range from 2 nm to 5 nm.

3. The power semiconductor device according to claim 2, wherein the channel length L_{ch} is less than 0.5 μm.

4. The power semiconductor device according to claim 2, wherein the channel length L_{ch} is less than 0.3 μm.

5. The power semiconductor device according to claim 2, wherein a doping concentration in the compensation layer is at least 1·10¹⁸ cm⁻³.

6. The power semiconductor device according to claim 5, wherein the doping concentration in the compensation layer is at least 5·10¹⁸ cm⁻³.

7. The power semiconductor device according to claim 1, wherein the channel region doping concentration is less than 5·10¹⁷ cm⁻³ and the body main region doping concentration is between 1·10¹⁸ cm⁻³ and 5·10¹⁹ cm⁻³.

8. The power semiconductor device according to claim 1, wherein the channel length L_{ch} is less than 0.5 μm.

9. The power semiconductor device according to claim 1, wherein the channel length L_{ch} is less than 0.3 μm.

10. The power semiconductor device according to claim 1, wherein a doping concentration in the compensation layer is at least 1·10¹⁸ cm⁻³.

11. The power semiconductor device according to claim 10, wherein the doping concentration in the compensation layer is at least 5·10¹⁸ cm⁻³.

12. The power semiconductor device according to claim 1, wherein the channel region doping concentration is between 1·10¹⁷ cm⁻³ and 5·10¹⁷ cm⁻³ and the body main region doping concentration is between 1·10¹⁸ cm⁻³ and 5·10¹⁹ cm⁻³.

13. The power semiconductor device according to claim 1, wherein the channel region doping concentration is at least 1·10¹⁷ cm⁻³, and the body main region doping concentration is at least 1·10¹⁸ cm⁻³.

14. The power semiconductor device according to claim 1, wherein the substrate layer, the body layer, the compensation layer and the source layer are silicon carbide layers.

15. The power semiconductor device according to claim 1, further comprising a well region of the second conductivity type, wherein the well region is directly adjacent to the gate insulation layer below a bottom of the gate electrode, and wherein the well region is laterally-aligned with the gate insulation layer.

16. A method for manufacturing a power semiconductor device according to claim 1, the method comprising:
providing a first semiconductor layer of a first conductivity type, the first semiconductor layer having a first main side and a second main side opposite to the first main side, the first semiconductor layer forming a substrate layer in the power semiconductor device;
forming a second semiconductor layer of a second conductivity type on the first main side of the first semiconductor layer to be in direct contact with the first semiconductor layer, the second semiconductor layer forming a body layer in the power semiconductor device;
doping a first portion of the second semiconductor layer with an impurity of the second conductivity type such that the first portion of the second semiconductor layer has a higher doping concentration than a remaining portion of the second semiconductor layer, the first portion of the second semiconductor layer forming a body main region in the body layer in the power semiconductor device; forming a third semiconductor layer of the first conductivity type fully overlapping the remaining portion of the second semiconductor layer and partially overlapping the first portion of the second semiconductor layer, the third semiconductor layer separated from the first semiconductor layer by the second semiconductor layer, the third semiconductor layer forming a source layer in the power semiconductor device;
forming at least one trench penetrating through the third semiconductor layer into the second semiconductor layer by removing material of the third and second semiconductor layer;
applying an impurity of the first conductivity type into a sidewall of the at least one trench to form a semiconductor region of the first conductivity type, which connects the third semiconductor layer with the first semiconductor layer, the semiconductor region forming a compensation layer in the power semiconductor device, and forming a channel region in the body layer between compensation layer and the body main region;
deepening the trench by removing material of the second and first semiconductor layer such that the deepened trench penetrates into the first semiconductor layer;
forming an insulation layer covering the sidewall and a bottom of the at least one deepened trench, the insulation layer forming a gate insulation layer in the power semiconductor device; and
forming an electrode layer in the at least one deepened trench, the electrode layer being electrically insulated from the first semiconductor layer, the second semiconductor layer, the third semiconductor layer and the semiconductor region of the first conductivity type by the insulation layer, the electrode layer forming a gate electrode in the power semiconductor device;
wherein the channel region in the body layer extends from the source layer to the substrate layer and a body main region doping concentration is higher than a channel region doping concentration;
wherein the channel region is defined as a portion of the body layer that has a distance of less than 0.1 μm from the compensation layer, where
$${L}_{c h} > 4 √ ( \frac{( {ɛ}_{C R} {c}_{COMP} {t}_{GI} )}{{ɛ}_{GI}} ) ,$$
where L_{ch} is a channel length, ε_{CR} is a permittivity of the channel region, ε_{GI} is a permittivity of the gate insulation layer, t_{COMP} is a thickness of the compensation layer in a direction perpendicular to an interface between the gate insulation layer and the compensation layer, and t_{GI} is a thickness of the gate insulation layer; and
the thickness t_{COMP} of the compensation layer being in a range from 1 nm to 10 nm.

17. The method for manufacturing the power semiconductor device according to claim 16, wherein applying the impurity of the first conductivity type into the sidewall of the at least one trench is performed by angled ion implantation having an implantation angle between 20 degrees and 6o degrees.

18. The method for manufacturing the power semiconductor device according to claim 16, wherein applying the impurity of the first conductivity type into the sidewall of the at least one trench is performed by plasma immersion ion implantation.

19. The method for manufacturing the power semiconductor device according to claim 16, wherein a semiconductor well region of the second conductivity type is formed below a bottom of the at least one deepened trench by applying an impurity of the second conductivity type into the first semiconductor layer through the bottom of the at least one deepened trench.

20. The method for manufacturing the power semiconductor device according to claim 19, further comprising forming the trench and the semiconductor well region using a same mask to self-align the semiconductor well region with the trench.

21. The method for manufacturing the power semiconductor device according to claim 16, wherein the third semiconductor layer is formed by applying an impurity of the first conductivity type into the second semiconductor layer.

22. The method for manufacturing the power semiconductor device according to claim 16, wherein the channel region doping concentration is less than 5·10¹⁷ cm⁻³, and the body main region doping concentration is between 1·10¹⁸ cm⁻³ and 5·10¹⁹ cm⁻³.

23. The method for manufacturing the power semiconductor device according to claim 16, wherein the channel region doping concentration is between 1·10¹⁷ cm⁻³ and 5·10¹⁷ cm⁻³, and the body main region doping concentration is between 1·10¹⁸ cm⁻³ and 5·10¹⁹ cm⁻³.

24. The method for manufacturing the power semiconductor device according to claim 16, wherein the channel region doping concentration is at least 1·10¹⁷ cm⁻³, and the body main region doping concentration is at least 1·10¹⁸ cm⁻³.
